(19) United States
(12) Patent Application Publication
(10) Pub. No.: US 2008/0085573 A1
(43) Pub. Date: Apr. 10, 2008

(54) UNDERFILL DISPENSE AT SUBSTRATE APERTURE

(75) Inventors: Charles Anthony Odegard, McKinney, TX (US); Marvin Wayne Cowens, Plano, TX (US); Leon Stiborek, Dallas, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/947,584

(22) Filed: Nov. 29, 2007

Related U.S. Application Data
(62) Division of application No. 11/109,259, filed on Apr. 19, 2005, now abandoned.

(51) Int. Cl. H01L 21/56

(52) U.S. Cl. 438/127; 257/E21.503

(57) ABSTRACT

Disclosed are methods for dispensing underfill material in an IC assembly having a die mounted on a substrate with a gap therebetween. One or more aperture is provided in the substrate for receiving underfill material into the gap. Underfill material is dispensed into the gap through the one or more apertures, thereby filling the gap with underfill material and providing a favorable flow rate and improved underfilling. Embodiments of the invention are disclosed in which capillary action, a vacuum, or positive pressure, are used to assist in the flow of the underfill material.

This application is a division of U.S. patent application Ser. No. 11/109,259 (Docket No. TI-39460) filed on Apr. 19, 2005, the entirety of which is incorporated herein by reference.

### TECHNICAL FIELD

The invention relates to the manufacture of integrated circuit assemblies. More particularly, the invention relates to the dispensation of underfill material between an IC device and a substrate.

### BACKGROUND

Semiconductor devices are subject to many competing design goals. Since it is very often desirable to minimize the size of electronic apparatus, surface mount semiconductor devices are often used due to their small footprint. Solder nodules or “bumps” having spherical, near-spherical, or other shapes are frequently used to join an IC to a substrate, such as a printed circuit board (PCB). The IC and substrate have corresponding metallized locations generally known as contact points, or bond pads. The components are aligned, typically using sophisticated optical aligning tools. Solder bumps positioned at the prepared metallized locations are heated, and solder bonds are formed between the contact points upon cooling. When completed, the IC-to-substrate assembly solder joints are typically “blind,” that is, they are not readily accessible for visual inspection. Often the gap between the IC and substrate is filled with a dielectric underfill material. The IC assembly is then encapsulated in a protective plastic package in order to in order to provide increased strength and protection.

Among the problems encountered with packaged IC assemblies, some of the most common and debilitating are the separation of layers, and open or short circuits caused by separation of materials, or the ingress of moisture between separated materials. For these reasons, void-free underfill processes and materials are highly desirable. Various combinations of underfill materials, dispensing patterns, and flow techniques have been used in efforts to reduce the formation of voids and reduce underfill process time. Common underfill dispensing techniques include “I” pass dispensing as shown in the cut-away view of an IC assembly 10 of FIG. 1 (prior art). The IC assembly 10 is shown during the dispensation of underfill material 12 in a view looking down on the gap between a die (cut away) and substrate 16. A dispensing needle (not shown) makes one or more passes along one edge 18 of the gap between the die and substrate and the underfill material 12 flows into the gap by capillary action or by the application of vacuum or suction force. Another common underfill dispensing technique is L-dispensing, as shown in FIG. 2, in which underfill material 12 is dispensed along two adjacent edges 18 of the gap. As with I-dispensing, the underfill fluid 12 may be pulled into the gap by capillary action or may be assisted by the use of external force. It is also known to use “U” dispensing patterns in a similar manner, and also to attempt to supplement I-dispensed, L-dispensed, or U-dispensed underfill fluid flow using external dams at one or more edges of the gap.

Problems persist in the efforts to achieve void-free underfills while optimizing throughput. Leaving aside the properties of the underfill fluid itself, the geometry of the die, substrate, and solder bumps in an assembly also have an effect on underfill fluid flow rate and coverage. In general, smaller vertical gaps increase flow rate and larger horizontal distances tend to reduce flow rate. The flow rate is also increased as the density of solder bumps increases, due to the stronger capillary action provided by the increased surface area. Fillets are often formed at the edges of the die-substrate gap during the underfill process. Dispensing a relatively large volume of underfill material can enhance flow, assure an adequate supply of fluid, and reduce voids, but excessive fillet size can increase stress on the edges of the completed package. Generally, stress increases with distance from the center of the die, and the larger the die, the greater the stress. Efforts to increase flow rate by force such as pumps and vacuums are sometimes successful. However, in addition to increasing flow rate, prevention of void formation is a challenge. Voids form when air becomes entrapped by the flowing underfill material. Flow rate, flow pattern, temperature, drag, and fluid viscosity are all intertwined in the completion of the underfill process and in the potential formation of voids. Many instances of void formation can be attributed to the differences in flow rate in different areas of an assembly. For example, in assemblies such as those shown in FIGS. 1 and 2 (prior art) having relatively high solder bump 20 density at the perimeter, faster flow of underfill material 12 at the perimeter can result in the entrapment of air pockets in the interior 22 of the device 10.

Due to these and other problems, improved methods for the manufacture of integrated circuit assemblies with reduced potential for underfill voids and increased throughput would be useful and advantageous in the arts.

### SUMMARY

In carrying out the principles of the present invention, in accordance with preferred embodiments thereof, IC assemblies are provided with underfill using methods designed to decrease the propensity for void formation.

According to one aspect of the invention, a method for dispensing underfill material into the gap between a die and substrate of an IC assembly includes steps for providing one or more apertures in the substrate for receiving underfill material into the gap. Underfill material is dispensed into the gap through one or more apertures, filling the gap with underfill material with a reduction in the propensity for the formation of voids.

According to another aspect of the invention, a method for dispensing underfill material through a substrate aperture to fill the gap between a substrate and die uses the application of force to the underfill material.

According to still another aspect of the invention, a method for dispensing underfill material through a substrate aperture to fill the gap between a substrate and die uses the application of force with a vacuum.

According to another aspect of the invention, a method for dispensing underfill material through a substrate aperture to fill the gap between a substrate and die uses the application of positive pressure.

According to one aspect of the invention, a method for dispensing underfill material into the gap between a die and substrate of an IC assembly includes steps for providing an aperture in the substrate for receiving underfill material into the gap wherein the aperture is positioned in the approximate geographic center of the substrate and material is dispensed into the gap through the aperture.

The invention has advantages including but not limited to improved underfill material dispensing and IC assemblies with improved strength and resistance to stress. These and other features, advantages, and benefits of the present invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 is a cut-away top view representing an example of prior art I-dispensed underfill;

FIG. 2 is a cut-away top view representing an example of prior art L-dispensed underfill;

FIG. 3A is a cut-away top view of an example of steps according to an example of a preferred embodiment of the invention; and

FIG. 3B is a cut-away top view of an example of further steps according to an example of a preferred embodiment of the invention.

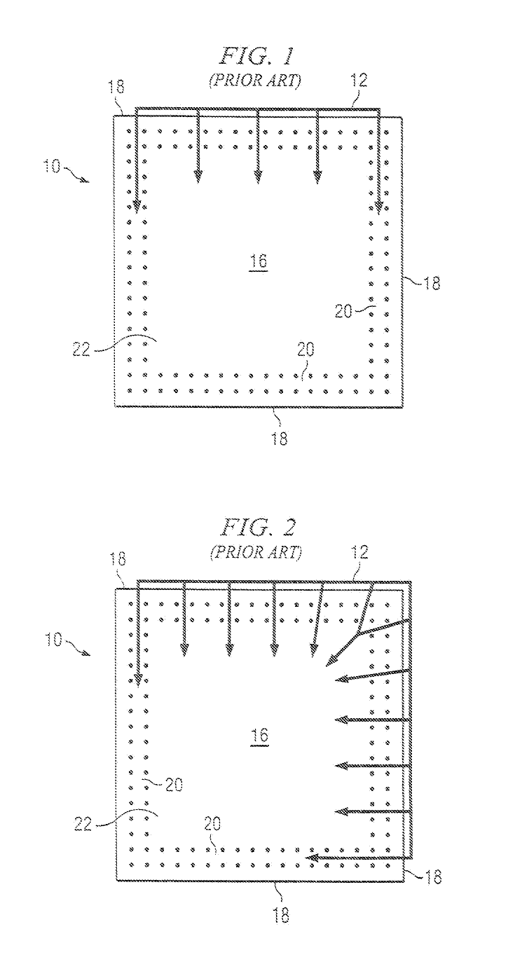

References in the detailed description correspond to like references in the various drawings unless otherwise noted. Descriptive and directional terms used in the written description such as first, second, top, bottom, upper, side, etc., refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### DETAILED DESCRIPTION

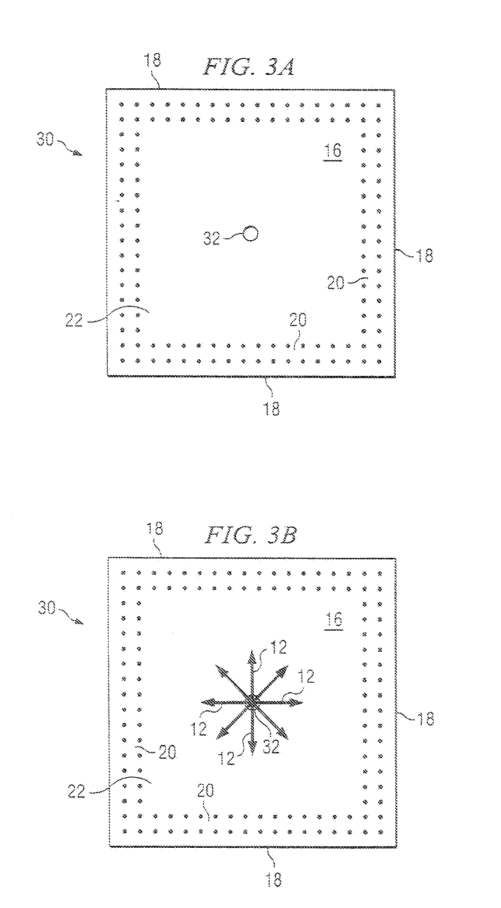

In general the invention provides methods for underfill dispensing in the manufacture of semiconductor device assemblies. FIG. 3A and FIG. 3B depict a cut-away top view looking down on the gap between a die (not shown) and substrate 16 in an IC assembly 30 using the invention. An aperture 32 is provided in the substrate 16. The aperture 32 provides communication with the gap to facilitate the dispensing of underfill material 12 into the gap from the outside of the substrate 16. Now referring primarily to FIG. 3B, the dispensing of underflow material 12 is represented by the arrows showing a generally radial flow of underfill material 12 into the gap from the aperture 32. The flow of underfill material 12 from the aperture 32 provides a relatively short flow path to the edges 18 of the assembly 30 for more rapid coverage. Also, the outward-flowing underfill material 12 forces air ahead of it, tending to decrease the occurrence of capture voids in the completed assembly 30. Additionally, the capture of impurities such as flux or other residue is made less likely due to the outward flow pattern. It should also be appreciated that the use of the invention in applications having higher bump density 20 at one or more edges 18 of the device, or the entire perimeter, provides additional advantages in distributing the underfill material 12 from a relatively slow-flowing area at the interior 22 of the device to the faster-flowing edges 18.

Those reasonably skilled in the arts will recognize that various alternatives exist for the adaptation of the methods of the invention to specific applications. For example, the dispensed underfill material 12 may be flowed using capillary action or may be assisted using force applied to the underfill material 12 such as by a vacuum or by pressurized dispensing means. Although the aperture 32 shown in the examples of FIGS. 3A and 3B is positioned in the approximate geographic center of the substrate 16, the use of other positions and/or multiple apertures is possible without departure form the scope of the invention.

The methods and apparatus of the invention provide advantages including but not limited to promoting electrical and mechanical bonding in IC assemblies. While the invention has been described with reference to certain illustrative embodiments, those described herein are not intended to be construed in a limiting sense. It will be appreciated by those skilled in the arts that the invention may be used with various types of semiconductor device packages. Various modifications and combinations of the illustrative embodiments as well as other advantages and embodiments of the invention will be apparent to persons skilled in the arts upon reference to the drawings, description, and claims.

What is claimed is:

1. A method for dispensing underfill material in an IC assembly having a die mounted on a substrate with a gap therebetween, comprising the steps of:
providing one or more apertures in the substrate for receiving underfill material into the gap;
dispensing underfill material into the gap through the aperture, thereby filling the gap with underfill material using an application of force to the underfill material.

2. A method for dispensing underfill material in an IC assembly according to claim 1 wherein the step of providing one or more apertures in the substrate further comprises the step of positioning one aperture in the approximate geographic center of the substrate.

3. A method for dispensing underfill material in an IC assembly according to claim 2 wherein the application of force to the underfill material further comprises the use of a vacuum.

4. A method for dispensing underfill material in an IC assembly according to claim 2 wherein the application of force to the underfill material further comprises the use of positive pressure.
